(19) United States
(12) Patent Application Publication
(10) Pub. No.: US 2009/0317982 A1
(43) Pub. Date: Dec. 24, 2009

(54) ATOMIC LAYER DEPOSITION APPARATUS AND METHOD FOR PREPARING METAL OXIDE LAYER

(75) Inventors: Ming Yen Li, Kaohsiung County (TW); Hsiao Che Wu, Taoyuan County (TW); De Long Chen, Taichung County (TW); Wen Li Tsai, Kaohsiung County (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., HSINCHU (TW)

(21) Appl. No.: 12/142,414

(22) Filed: Jun. 19, 2008

(51) Int. Cl. H01L 21/31; C23C 16/00

(52) U.S. Cl. 438/787; 118/725; 257/E21.24

(57) ABSTRACT

An atomic layer deposition apparatus comprises a reaction chamber, a heater configured to heat a semiconductor wafer positioned on the heater, an oxidant supply configured to deliver oxidant-containing precursors having different oxidant concentrations to the reaction chamber, and a metal supply configured to deliver a metal-containing precursor to the reaction chamber. The present application also discloses a method for preparing a dielectric structure comprising the steps of placing a substrate in a reaction chamber, performing a first atomic layer deposition process including feeding an oxidant-containing precursor having a relatively lower oxidant concentration and a metal-containing precursor to form an thinner interfacial layer on the substrate, and performing a second atomic layer deposition process including feeding the oxidant-containing precursor having an oxidant concentration higher than that used to grow the first metal oxide layer and the metal-containing precursor into the reaction chamber.

### BACKGROUND OF THE INVENTION

(A) Field of the Invention

The present invention relates to an atomic layer deposition (ALD) apparatus and method for preparing a dielectric structure, and more particularly, to an ALD apparatus and method for preparing a metal oxide layer in a two-step scheme.

(B) Description of the Related Art

As the size of semiconductor memory devices decreases, the technology for growing a uniform thin layer with respect to high-aspect-ratio trenches of a fine pattern has become the focus of much attention. To meet the requirements during the device size decrease, atomic layer deposition (ALD) has recently gained acceptance as a thin film deposition technique in semiconductor device manufacturing due to its excellent film property performance. The characteristic feature of ALD distinguishing it from the closely related CVD technique is that, in general, the substrate surface is alternately exposed to only one of several complementary chemical environments, i.e. a self-limiting film growth process based on sequential saturative surface reactions that are accomplished by pulsing the gaseous precursors on the substrate alternately and purging the reactor chamber with inert gases between the reactant pulses. By this way the self-limiting reactions are forced to be entirely on surface, which ensuring excellent conformality along with large area uniformity as well as digital thickness control by selecting the number of deposition cycles repeated.

An example of the ALD method includes feeding a single vaporized precursor (first precursor) to a reaction chamber in order to form a first monolayer over a substrate in the reaction chamber. Thereafter, the flow of the first precursor is ceased and an inert purge gas is flowed through the reaction chamber in order to remove any remaining first precursor not adhering to the substrate from the reaction chamber. Subsequently, a second vapor precursor (second precursor) different from the first precursor is flowed to the reaction chamber in order to form a second monolayer over the first monolayer. The second monolayer might react with the first monolayer, and the above processes can be repeated until a stacked structure with desired thickness and composition has been formed over the substrate.

### SUMMARY OF THE INVENTION

One aspect of the present invention provides an ALD apparatus and method for preparing a dielectric structure in a two-step scheme, which can prepare a metal oxide layer with a thinner interfacial layer between the metal oxide layer and a substrate.

An atomic layer deposition apparatus for preparing a metal oxide layer according to this aspect of the present invention comprises a reaction chamber, a heater configured to heat a semiconductor wafer positioned on the heater, an oxidant supply configured to deliver oxidant-containing precursors having different oxidant concentrations to the reaction chamber, and a metal supply configured to deliver a metal-containing precursor to the reaction chamber.

Another aspect of the present invention provides a method for preparing a dielectric structure comprising the steps of placing a substrate in a reaction chamber, performing a first atomic layer deposition process including feeding an oxidant-containing precursor having a relatively lower oxidant concentration and a metal-containing precursor to form the first metal oxide layer and an interfacial layer on the substrate, and performing a second atomic layer deposition process including feeding the oxidant-containing precursor having a oxidant concentration higher than that used to grow the first metal oxide layer and the metal-containing precursor into the reaction chamber.

The present invention provides a two-step scheme ALD by delivering oxidant-containing precursors having different oxidant concentrations to the reaction chamber. Consequently, the two-step scheme ALD of the present invention can prepare the interfacial layer with decreased thickness.

The foregoing has outlined rather broadly the features and technical advantages of the present invention in order that the detailed description of the invention that follows may be better understood. Additional features and advantages of the invention will be described hereinafter, which form the subject of the claims of the invention.

### BRIEF DESCRIPTION OF THE DRAWINGS

The objectives and advantages of the present invention will become apparent upon reading the following description and upon reference to the accompanying drawings in which:

FIG. 1 illustrates an ALD apparatus according to one embodiment of the present invention;

FIG. 2 illustrates an ALD apparatus according to another embodiment of the present invention;

FIG. 3 and FIG. 4 illustrate a method for preparing a dielectric structure according to one embodiment of the present invention;

FIG. 5 illustrates three TEM images of dielectric layers prepared by the ALD method with different oxidant concentrations; and

FIG. 6 illustrates two TEM images of dielectric layers prepared by the ALD method according to the present invention and the prior art.

### DETAILED DESCRIPTION OF THE INVENTION

While the conventional ALD apparatus can provide a thin layer having a high aspect ratio, in addition to having a good uniformity over a trench, it has the major disadvantage of a low deposition rate. The deposition rate in the conventional ALD apparatus can be increased by increasing the precursor concentration; however, increasing the precursor concentration results in increased thickness of the interfacial layer, which is detrimental to the electrical properties of the ALD layer. To resolve this trade-off, the present invention provides a two-step ALD scheme, which can be applied to preparing a metal oxide layer with a restrained interfacial layer at a higher deposition rate.

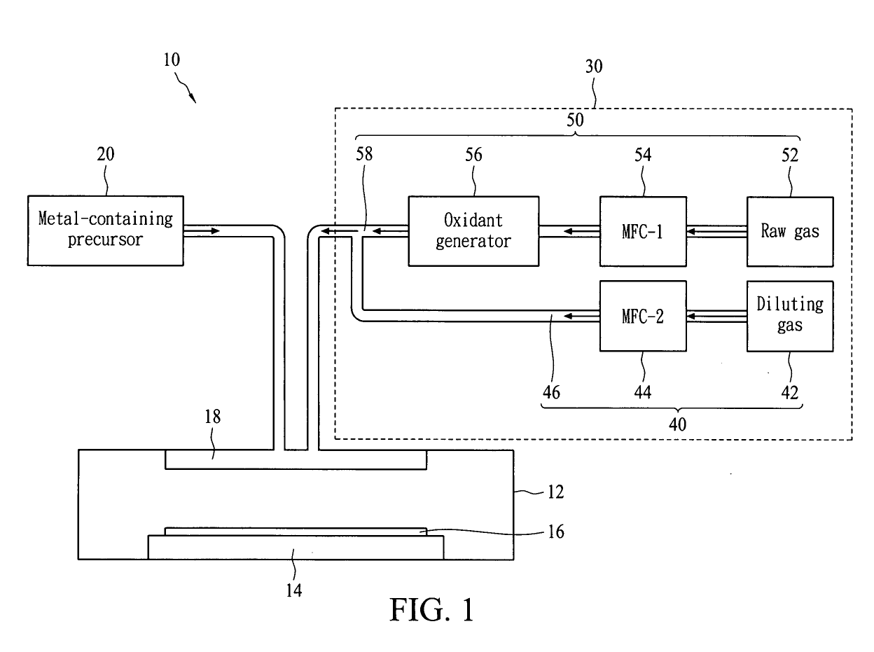

FIG. 1 illustrates an ALD apparatus 10 according to one embodiment of the present invention. The ALD apparatus 10 comprises a reaction chamber 12, a heater 14 configured to heat a semiconductor wafer 16 positioned on the heater 14, a metal supply 20 configured to deliver a metal-containing precursor to the reaction chamber 12, an oxidant supply 30 configured to deliver oxidant-containing precursors having different oxidant concentrations to the reaction chamber 12, and a shower head 18 configured to dispense the oxidant-containing precursor and metal-containing precursor to the semiconductor wafer 16. The metal supply 20 can be configured to provide the metal-containing precursor containing metal may include ruthenium (Ru), aluminum (Al), tungsten (W), zirconium (Zr), hafnium (Hf), titanium (Ti), and tantalum (Ta).

The oxidant supply 30 comprises an oxidant-generating module 50 configured to generate the oxidant-containing precursor having a high oxidant concentration (second oxidant concentration) and a diluting module 40 configured to dilute the oxidant-containing precursor from the high oxidant concentration down to a low oxidant concentration (first oxidant concentration). In one embodiment, the high oxidant concentration is in a range from 210 to 400 G/M³, and the low oxidant concentration is in a range from 50 to 200 G/M³. The oxidant-generating module 50 includes a raw source 52 configured to provide a raw gas, an oxidant generator 56 configured to convert a portion of the raw gas into an oxidant, a mass flow controller (MFC-1) 54 configured to control the flow of the raw gas to the oxidant generator 56, and a pipe 58 connecting the oxidant generator 56 and the reaction chamber 12 for delivering the oxidant-containing precursor to the shower head 18.

For example, the raw source 52 can be an oxygen cylinder configured to provide oxygen gas (O₂), the oxidant generator 56 is configured to convert a portion of the oxygen gas into ozone (O₃, strong oxidant), and the mass flow controller (MFC-1) 54 is configured to control the flow of the oxygen gas to the oxidant generator 56. The diluting module 40 includes a diluting-gas source 42 configured to provide a diluting gas, a mass flow controller (MFC-2) 44 configured to control the flow of the diluting gas to the pipe 58, and a pipe 46 connecting the mass flow controller 44 and the pipe 58. The diluting gas can be the raw gas or an inert gas, and the pipe 46 may be optionally designed to connect the mass flow controller 44 and the shower head 18 in the reaction chamber 12.

Without enabling the diluting module 40, the oxidant-generating module 50 can deliver the oxidant-containing precursor having the high oxidant (ozone) concentration directly to the reaction chamber 12. To provide the oxidant-containing precursor having the low oxidant (ozone) concentration to the reaction chamber 12, the diluting module 40 is enabled to deliver the raw gas or the inert gas to the pipe 58 such that the concentration of the oxidant-containing precursor to the reaction chamber 12 is changed from the high oxidant concentration to a low oxidant concentration. Furthermore, the diluting module 40 can be disabled so that the oxidant-generating module 50 can again provide the oxidant-containing precursor having the high oxidant (ozone) concentration to the reaction chamber 12. Consequently, the oxidant supply 30 can optionally deliver the oxidant-containing precursors having different oxidant concentrations (high or low) of oxidant (ozone) to the reaction chamber 12.

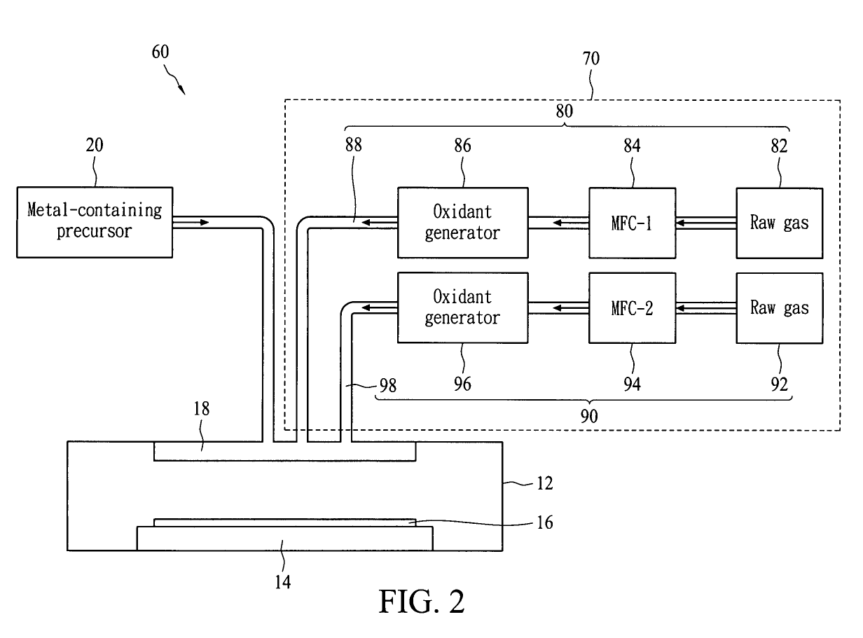

FIG. 2 illustrates an ALD apparatus 60 according to another embodiment of the present invention. The ALD apparatus 60 comprises a reaction chamber 12, a heater 14 configured to heat a semiconductor wafer 16 positioned on the heater 14, a metal supply 20 configured to deliver a metal-containing precursor to the reaction chamber 12, an oxidant supply 70 configured to deliver oxidant-containing precursors having different oxidant concentrations to the reaction chamber 12, and a shower head 18 configured to dispense the oxidant-containing precursor and metal-containing precursor to the semiconductor wafer 16. The metal supply 20 can be configured to provide the metal-containing precursor containing metal may include ruthenium (Ru), aluminum (Al), tungsten (W), zirconium (Zr), hafnium (Hf), titanium (Ti), and tantalum (Ta).

The oxidant supply 70 comprises two oxidant-generating modules 80 and 90 configured to generate the oxidant-containing precursors having different oxidant concentrations. The oxidant-generating module 80 includes a raw source 82 configured to provide a raw gas, an oxidant generator 86 configured to convert a portion of the raw gas into an oxidant, a mass flow controller (MFC-1) 84 configured to control the flow of the raw gas to the oxidant generator 86, and a pipe 88 connecting the oxidant generator 86 and the shower head 18 in the reaction chamber 12. The oxidant-generating module 90 includes a raw source 92 configured to provide a raw gas, an oxidant generator 96 configured to convert a portion of the raw gas into an oxidant, a mass flow controller (MFC-2) 94 configured to control the flow of the raw gas to the oxidant generator 96, and a pipe 98 connecting the oxidant generator 96 and the shower head 18 in the reaction chamber 12.

For example, the raw sources 82 and 92 can be oxygen cylinders configured to provide oxygen gas, the oxidant generators 86 and 96 can be configured to convert a portion of the oxygen gas into ozone (strong oxidant), and the mass flow controllers (MFC-1) 84 and (MFC-2) 94 are configured to control the flow of the oxygen gas to the oxidant generators 86 and 96. The oxidant-generating module 80 can be configured to generate the oxidant-containing precursor having the high oxidant (ozone) concentration to the reaction chamber 12, while the second oxidant-generating module 90 can be configured to generate the oxidant-containing precursor having the low oxidant (ozone) concentration to the reaction chamber 12.

For example, the oxidant-generating module 90 can be disabled, while the oxidant-generating module 80 is enabled to deliver the oxidant-containing precursor having the high oxidant (ozone) concentration to the shower head 18 in the reaction chamber 12. Alternatively, the oxidant-generating module 80 can be disabled, while the oxidant-generating module 90 is enabled to deliver the oxidant-containing precursor having the low oxidant (ozone) concentration to the shower head 18 in the reaction chamber 12. Thus, the oxidant supply 30 can optionally deliver the oxidant-containing precursors having different concentrations (high or low) of oxidant (ozone) to the reaction chamber 12.

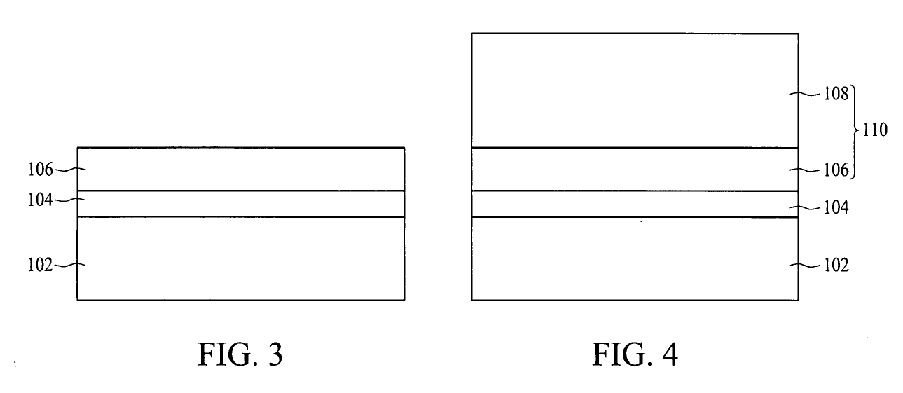

FIG. 3 and FIG. 4 illustrate a method for preparing a dielectric structure 110 according to one embodiment of the present invention. Referring to FIG. 3, a substrate 102 is placed in a reaction chamber, and a first ALD process is performed to form an interfacial layer 104 on the substrate 102 and a first metal oxide layer 106 on the interfacial layer 104. The first ALD process includes feeding an oxidant-containing precursor having a low oxidant concentration and feeding a metal-containing precursor to the reaction chamber in an alternative manner for a first predetermined cycle, with the step of purging the inner gas to the reaction chamber between feeding the oxidant-containing precursor and feeding the metal-containing precursor. The oxidant can be ozone, and the metal-containing precursor containing metal may include ruthenium (Ru), aluminum (Al), tungsten (W), zirconium (Zr), hafnium (Hf), titanium (Ti), and tantalum (Ta).

The substrate 102 may include silicon, the interfacial layer 104 is a metal silicate layer formed because the silicon substrate 102 could be oxidized by oxidant as well as reacted with metal-containing precursor, and the first metal oxide layer 106 is formed by repeating surface reactions of oxidant and oxidant-containing precursor. In particular, the first ALD process feeds the oxidant-containing precursor having the low oxidant concentration to slow down the growing of the interfacial layer 104 by the oxidation of the metal and the silicon, so that the interfacial layer 104 can be prepared with a decreased thickness.

Referring to FIG. 4, after the first metal oxide layer 106 is formed, a second ALD process is then performed to form a second metal oxide layer 108 on the first metal oxide layer 106 so as to form the desired dielectric structure 110. The second ALD process includes feeding the oxidant-containing precursor having a high oxidant concentration and feeding the metal-containing precursor to the reaction chamber in an alternative manner for a second predetermined cycle, with the step of purging the inner gas to the reaction chamber between feeding the oxidant-containing precursor and feeding the metal-containing precursor.

In particular, the second metal oxide layer 108 is formed of metal from metal-containing precursor and oxygen by repeating surface reactions of oxidant and oxidant-containing precursor. In addition, the oxidant concentration of the oxidant-containing precursor during the second ALD process is larger than that during the first ALD process, so that the growing of the second metal oxide layer 108 during the second ALD process is faster than the growing of the first metal oxide layer 106 during the first ALD process. Furthermore, the second predetermined cycle is longer than the first predetermined cycle, so that the second metal oxide layer 108 is thicker than the first metal oxide layer 106, i.e., the second metal oxide layer 108 is the majority of the dielectric structure 110.

One approach to supplying the oxidant-containing precursor having the low oxidant concentration is to generate the oxidant-containing precursor having the high oxidant concentration, then dilute the oxidant-containing precursor from the high oxidant concentration to the low oxidant concentration, and transferring the diluted oxidant-containing precursor having the low oxidant concentration to the reaction chamber. Subsequently, the supplying of the oxidant-containing precursor having a high oxidant concentration may be achieved by ending the diluting of the oxidant-containing precursor so that the oxidant-containing precursor having the high oxidant concentration can be transferred directly to the reaction chamber.

Another approach to supplying the oxidant-containing precursor having the low oxidant concentration is to generate the oxidant-containing precursor having the low oxidant concentration, and transferring the oxidant-containing precursor having the low oxidant concentration to the reaction chamber. Subsequently, the supplying of the oxidant-containing precursor having the high oxidant concentration may be achieved by stopping the transferring of the oxidant-containing precursor having the low oxidant concentration, generating the oxidant-containing precursor having the high oxidant concentration, and transferring the oxidant-containing precursor having the high oxidant concentration to the reaction chamber.

In particular, the substrate 102 can be a silicon substrate, and the dielectric structure 110 serves as a gate dielectric on the substrate 102, i.e., the present invention can be applied to preparing the gate dielectric with very small thickness for the advanced fabrication technology. Furthermore, the substrate 102 may include a capacitor structure such as semiconductor-insulator-semiconductor structure having a capacitor contact and a bottom electrode on the capacitor contact, and the dielectric structure 110 serves as the insulator sandwiched between two conductors of the capacitor structure. In other words, the present invention can be applied to preparing the high-k dielectric for the capacitor. The metal-containing precursor in the approach containing metal may include ruthenium (Ru), aluminum (Al), tungsten (W), zirconium (Zr), hafnium (Hf), titanium (Ti), and tantalum (Ta) and alloys compounded of these materials.

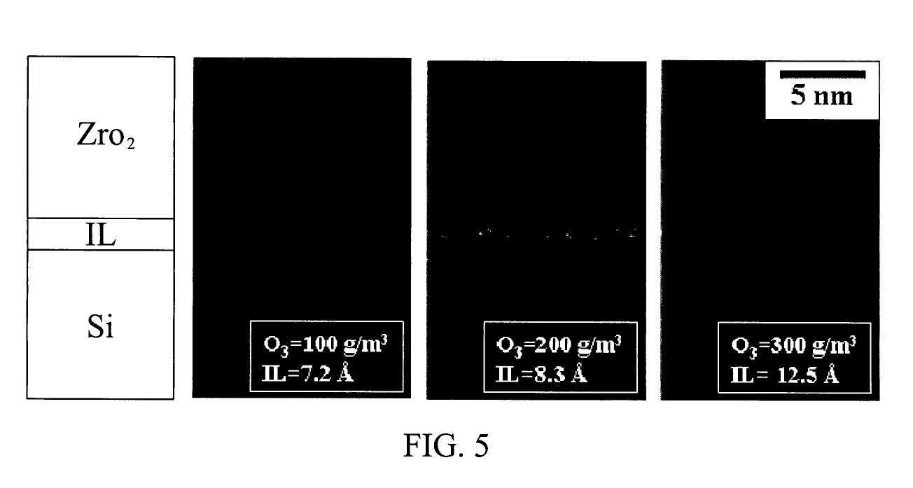

FIG. 5 illustrates three TEM images of dielectric layers prepared by the ALD method with different oxidant concentrations. The dielectric layers in the TEM images are prepared by feeding the oxidant-containing precursor having different oxidant concentrations during the ALD process, and the oxidant (ozone) concentrations are 100 g/cm³, 200 g/cm³, and 300 g/cm³, respectively, the resulting thicknesses of the interfacial layer (IL) are 7.2 angstroms, 8.3 angstroms, and 12.8 angstroms, respectively, i.e., the IL thickness decreases as the oxidant (ozone) concentration is reduced. In other words, reducing the oxidant (ozone) concentration of the ALD process can decrease the thickness of the interfacial layer.

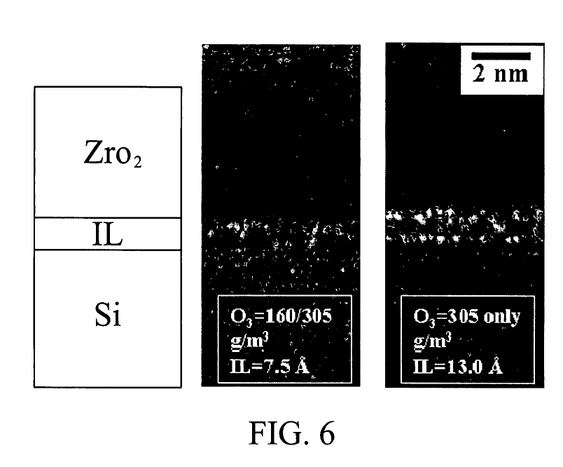

FIG. 6 illustrates two TEM images of dielectric layers prepared by the ALD method according to the present invention (left) and the prior art (right). According to the present invention, the dielectric layer is prepared by feeding the oxidant-containing precursor having the low oxidant (ozone) concentration (160 g/cm³) during the first ALD process and feeding the oxidant-containing precursor having the high oxidant (ozone) concentration (305 g/cm³) during the second ALD process. In contrast, according to the prior art, the dielectric layer is prepared by feeding the oxidant-containing precursor having a constant oxidant (ozone) concentration (305 g/cm³) during the entire ALD process.

The thickness of the interfacial layer (IL) is 7.5 angstroms according to the two-step scheme ALD of the present invention, and the thickness of the interfacial layer (IL) is up to 13.0 angstroms according to the one-step scheme ALD of the prior art, i.e., the two-step scheme ALD of the present invention can prepare the interfacial layer with reduced thickness. The properties of the dielectric layers are illustrated in the following Table 1, which clearly shows that the thinner interfacial layer has higher dielectric constant, lower trap density, and lower leakage.

TABLE 1

| | | | Dielectric | | Leak- |
|---|---|---|---|---|---|
| Oxidant | | | constant | Interfacial trap | age |
| concentration | IL thickness | | (k) | density | (a.u.) |
| 165/305 | 7.5 | angstroms | 14 | 1.37(10¹³/cm³eV) | −1.85 |
| (g/cm³) | | | | | |
| 305 | 13.0 | angstroms | 13 | 1.42(10¹³/cm³eV) | −2.01 |
| (g/cm³) | | | | | |

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An atomic layer deposition apparatus, comprising:
a reaction chamber;
a heater configured to heat a semiconductor wafer positioned thereon;
an oxidant supply configured to deliver oxidant-containing precursors having different oxidant concentrations to the reaction chamber; and
a metal supply configured to deliver a metal-containing precursor to the reaction chamber.

2. The atomic layer deposition apparatus of claim 1, wherein the oxidant supply includes two oxidant-generating modules configured to generate the oxidant-containing precursors having different oxidant concentrations.

3. The atomic layer deposition apparatus of claim 2, wherein each of the oxidant-generating modules includes:
a raw source configured to provide a raw gas;
an oxidant generator configured to convert a portion of the raw gas into an oxidant; and
a mass flow controller configured to control the flow of the raw gas to the oxidant generator, wherein the raw gas is oxygen, and the oxidant is ozone.

4. The atomic layer deposition apparatus of claim 1, wherein the oxidant supply includes:
an oxidant-generating module configured to generate the oxidant-containing precursor having a second oxidant concentration; and
a diluting module configured to dilute the oxidant-containing precursor to a first oxidant concentration smaller than the second oxidant concentration, the second oxidant concentration being higher than the first oxidant concentration.

5. The atomic layer deposition apparatus of claim 4, wherein the oxidant-generating module includes:
a raw source configured to provide a raw gas;
an oxidant generator configured to convert a portion of the raw gas into an oxidant;
a mass flow controller configured to control the flow of the raw gas to the oxidant generator; and
a pipe connecting the oxidant generator and the reaction chamber.

6. The atomic layer deposition apparatus of claim 5, wherein the raw gas is oxygen gas or gaseous water, and the oxidant is ozone gas or gaseous water.

7. The atomic layer deposition apparatus of claim 4, wherein the diluting module includes:
a diluting-gas source configured to provide a diluting gas; and
a mass flow controller configured to control the flow of the diluting gas to the pipe, wherein the diluting gas is the raw gas or an inert gas.

8. The atomic layer deposition apparatus of claim 1, wherein the metal supply is configured to provide the metal-containing precursor containing metal include ruthenium (Ru), aluminum (Al), tungsten (W), zirconium (Zr), hafnium (Hf), titanium (Ti), and tantalum (Ta).

9. The atomic layer deposition apparatus of claim 1, further comprising a shower head configured to dispense the oxidant-containing precursor and metal-containing precursor to the semiconductor wafer.

10. A method for preparing a dielectric structure, comprising the steps of:
placing a substrate in a reaction chamber;
performing a first atomic layer deposition process to form a first metal oxide layer and an interfacial layer on the substrate, including feeding an oxidant-containing precursor having a first oxidant concentration and a metal-containing precursor into the reaction chamber; and
performing a second atomic layer deposition process to form a second metal oxide layer on the first metal oxide layer, including feeding the oxidant-containing precursor having a second oxidant concentration and the metal-containing precursor into the reaction chamber, the second oxidant concentration being higher than the first oxidant concentration.

11. The method for preparing a dielectric structure of claim 10, wherein the feeding of the oxidant-containing precursor having the first oxidant concentration includes:
generating the oxidant-containing precursor having the first oxidant concentration; and
transferring the oxidant-containing precursor having the first oxidant concentration to the reaction chamber.

12. The method for preparing a dielectric structure of claim 10, wherein the feeding of the oxidant-containing precursor having the second oxidant concentration includes:
stopping the transferring of the oxidant-containing precursor having the first oxidant concentration;
generating the oxidant-containing precursor having the second oxidant concentration; and
transferring the oxidant-containing precursor having the second oxidant concentration to the reaction chamber.

13. The method for preparing a dielectric structure of claim 10, wherein the feeding of the oxidant-containing precursor having the first oxidant concentration includes:
generating the oxidant-containing precursor having the second oxidant concentration;
diluting the oxidant-containing precursor to the first oxidant concentration; and
transferring the oxidant-containing precursor having the first oxidant concentration to the reaction chamber.

14. The method for preparing a dielectric structure of claim 10 wherein the feeding of the oxidant-containing precursor having the second oxidant concentration includes:
ending the diluting of the oxidant-containing precursor to generate the oxidant-containing precursor having the second oxidant concentration;
transferring the oxidant-containing precursor having the second oxidant concentration to the reaction chamber.

15. The method for preparing a dielectric structure of claim 10, wherein the oxidant-containing precursor includes ozone gas or gaseous wafer.

16. The method for preparing a dielectric structure of claim 10, wherein the dielectric structure serves as a gate dielectric on a semiconductor substrate.

17. The method for preparing a dielectric structure of claim 10, wherein the substrate is a silicon substrate and the interfacial layer is a silicon oxide layer and/or a metal silicate layer on the silicon substrate.

18. The method for preparing a dielectric structure of claim 10, wherein the dielectric structure serves as an insulator sandwiched between two conductors of a capacitor structure.

19. The method for preparing a dielectric structure of claim 10, wherein the first oxidant concentration is in a range from 50 to 200 G/M³.

20. The method for preparing a dielectric structure of claim 10, wherein the second oxidant concentration is in a range from 210 to 400 G/M³.
